(19) United States
(12) Patent Application Publication
(10) Pub. No.: US 2025/0125788 A1
(43) Pub. Date: Apr. 17, 2025

(54) DOUBLE-MODE SURFACE ACOUSTIC WAVE FILTER

(71) Applicant: Shenzhen Newsonic Technologies Co., Ltd., Shenzhen (CN)

(72) Inventors: Xin HE, Shenzhen (CN); Duan FENG, Shenzhen (CN); Haiting GAO, Shenzhen (CN)

(21) Appl. No.: 18/989,832

(22) Filed: Dec. 20, 2024

(30) Foreign Application Priority Data
Nov. 4, 2024 (CN) 202411557924.1

(51) Int. Cl. H03H 9/64; H03H 9/72

(52) U.S. Cl. CPC H03H 9/6433; H03H 9/725

(57) ABSTRACT

A double-mode surface acoustic wave (SAW) filter includes a piezoelectric substrate, a pair of reflectors disposed on the piezoelectric substrate, and N input and output interdigital transducer tracks (IDT-tracks) disposed on the piezoelectric substrate and between the pair of reflectors, and alternately arranged along a longitudinal direction. Each IDT-track includes a pair of comb electrodes with a plurality of fingers, and adjacent fingers have opposite polarities. A total number of fingers in each IDT-track is an odd number greater than or equal to 3.

### CROSS-REFERENCE TO RELATED APPLICATIONS

The application is based upon and claims priority to Chinese patent application No. 202411557924.1, filed on Nov. 4, 2024, the entire contents of which are incorporated herein by reference as part of the present application.

### FIELD

The present disclosure relates to the field of semiconductor devices and, in particular, to a surface acoustic wave device.

### BACKGROUND

Generally, receive filters have stringent requirements for indicators such as insertion loss and stop-band suppression, and there is a continuous demand for minimizing chip size in order to reduce costs. For the above reasons, receive filters generally use double-mode surface acoustic wave filters (referred to as “double-mode SAW filters” or “DMS filters”) or hybrid-type filters composed of DMS filters and series/parallel one-port resonators. In this structure, a reasonable design of parameters of interdigital electrodes of the DMS filter is critical to the overall performance of the filter, especially for insertion loss and stop-band suppression.

Using a Band66 receive filter (2110 MHz to 2200 MHZ) as an example, it is generally expected that the stop-band suppression level for the adjacent frequency bands Band3 (1710 MHz to 1785 MHZ) and Band1 (1920 MHz to 1980 MHZ) should be below −40 dB. This ensures optimal performance of the terminal equipment in accordance with the working requirements.

### SUMMARY

According to one aspect of the disclosure, a double-mode surface acoustic wave (DMS) filter is provided. The DMS filter includes a piezoelectric substrate, a pair of reflectors disposed on the piezoelectric substrate, and N interdigital transducer tracks (IDT-tracks) disposed on the piezoelectric substrate and between the pair of reflectors, and alternately arranged along a longitudinal direction. Each IDT-track including a pair of comb electrodes with a plurality of fingers, and adjacent fingers having opposite polarities. A total number of fingers in each IDT-track is an odd number greater than or equal to 3.

According to another aspect of the disclosure, a receive filter includes a double-mode surface acoustic wave (DMS) filter. The DMS filter includes a piezoelectric substrate, a pair of reflectors disposed on the piezoelectric substrate, and N interdigital transducer tracks (IDT-tracks) disposed on the piezoelectric substrate and between the pair of reflectors, and alternately arranged along a longitudinal direction. Each IDT-track including a pair of comb electrodes with a plurality of fingers, and adjacent fingers having opposite polarities. A total number of fingers in each IDT-track is an odd number greater than or equal to 3.

According to still another aspect of the disclosure, a duplexer includes a transmit filter, and a receive filter. The receive filter includes a double-mode surface acoustic wave (DMS) filter. The DMS filter includes a piezoelectric substrate, a pair of reflectors disposed on the piezoelectric substrate, and N interdigital transducer tracks (IDT-tracks) disposed on the piezoelectric substrate and between the pair of reflectors, and alternately arranged along a longitudinal direction. Each IDT-track including a pair of comb electrodes with a plurality of fingers, and adjacent fingers having opposite polarities. A total number of fingers in each IDT-track is an odd number greater than or equal to 3.

### BRIEF DESCRIPTION OF THE DRAWINGS

The accompanying drawings, which are incorporated in and constitute a part of this application, illustrate disclosed embodiments and, together with the description, serve to explain the disclosed embodiments.

FIG. 1 schematically illustrates a top view of a double-mode surface acoustic wave (DMS) filter according to an embodiment of the present disclosure.

FIG. 2 is a table summarizing parameters of a first DMS filter included in a first Band66 receive filter, according to an embodiment of the present disclosure.

FIG. 3 is a graph of simulated frequency response for the first Band66 receive filter including the first DMS filter.

FIG. 4 is a table summarizing parameters of a second DMS filter included in a second Band66 receive filter, according to an embodiment of the present disclosure.

FIG. 5 is a graph of simulated frequency response for the second Band66 filter including the second DMS filter of the embodiment of the present disclosure.

FIG. 6 illustrates a hybrid-type receive filter according to an embodiment of the present disclosure.

FIG. 7 illustrates a duplexer according to an embodiment of the present disclosure.

### DETAILED DESCRIPTION

The text below provides a detailed description of the present disclosure in conjunction with specific embodiments illustrated in the attached drawings. However, these embodiments do not limit the present disclosure. The scope of protection for the present disclosure covers changes made to the structure, method, or function by persons having ordinary skill in the art on the basis of these embodiments.

To facilitate the presentation of the drawings in the present disclosure, the sizes of certain structures or portions may be enlarged relative to other structures or portions. Therefore, the drawings in the present disclosure are only for the purpose of illustrating the basic structure of the subject matter of the present disclosure. The same numbers in different drawings represent the same or similar elements unless otherwise represented.

Additionally, terms in the text indicating relative spatial position, such as “top,” “bottom,” “upper,” “lower,” “above,” “below,” and so forth, are used for explanatory purposes in describing the relationship between a unit or feature depicted in a drawing and another unit or feature therein. Terms indicating relative spatial position may refer to positions other than those depicted in the drawings when a device is being used or operated. For example, if a device shown in a drawing is flipped over, a unit which is described as being positioned “below” or “under” another unit or feature will be located “above” the other unit or feature. Therefore, the illustrative term “below” may include positions both above and below. A device may be oriented in other ways (e.g., rotated 90 degrees or facing another direction), and descriptive terms that appear in the text and are related to space should be interpreted accordingly. When a component or layer is said to be “above” another member or layer or “connected to” another member or layer, it may be directly above the other member or layer or directly connected to the other member or layer, or there may be an intermediate component or layer.

Embodiment of the present embodiment provide a double-mode surface acoustic wave (DMS) filter. The DMS filter includes a piezoelectric substrate, a pair of reflectors disposed on the piezoelectric substrate, and N input and output interdigital transducer tracks (IDT-tracks) disposed on the piezoelectric substrate and between the pair of reflectors. The N input and output IDT-tracks are alternately arranged along a longitudinal direction. Each one of the N input and output IDT-tracks includes a pair of comb electrodes with a plurality of fingers, and adjacent fingers pointing in opposite directions. N may be an odd number greater than or equal to 5.

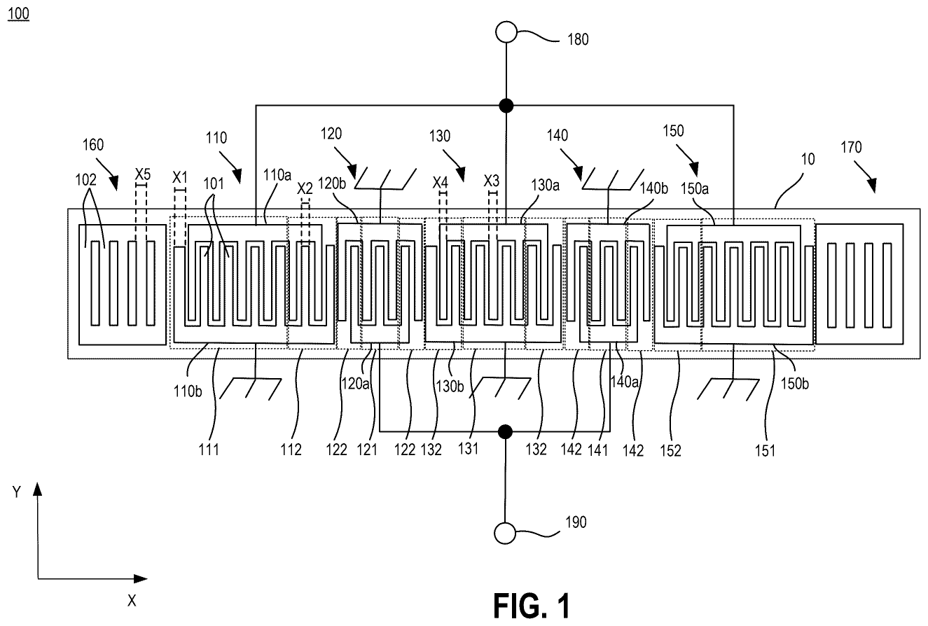

FIG. 1 schematically illustrates a top view of a double-mode surface acoustic wave (DMS) filter 100 according to an embodiment of the present disclosure. As illustrated in FIG. 1, DMS filter 100 includes a piezoelectric substrate 10, a pair of reflectors 160 and 170 disposed on piezoelectric substrate 10, and N input and output interdigital transducer tracks (IDT-tracks) 110, 120, 130, 140, and 150 (hereinafter referred to as “110-150”) disposed on piezoelectric substrate 10 and between the pair of reflectors 160 and 170. N may be any odd number greater than or equal to 5. The N input and output IDT-tracks 110-150 are alternately arranged along a longitudinal direction (X-axis direction in FIG. 1) along a major surface of piezoelectric substrate 10. Each input IDT-track is arranged next to an output IDT-track, and each output IDT-track is arranged next to an input IDT-track. Each one of IDT-tracks 110-150 includes a pair of comb electrodes with a plurality of fingers 101 extending in a transverse direction (Y-axis direction in FIG. 1) orthogonal to the longitudinal direction. The fingers 101 in the pair of comb electrodes are orientated (pointing) in opposite directions.

In the embodiment illustrated in FIG. 1, N is equivalent to 5. That is, DMS filter 100 in FIG. 1 includes five input and output IDT-tracks, namely IDT-tracks 110-150. Among these IDT-tracks 110-150, first IDT-track 110, third IDT-track 130, and fifth IDT-track 150 operate as input IDT-tracks, while second IDT-track 120 and fourth IDT-track 140 operate as output IDT-tracks. Each one of IDT-tracks 110-150 includes a pair of comb electrodes respectively connected between an input terminal 180 or an output terminal 190 and ground. For example, first IDT-track 110 includes comb electrodes 110a connected to input terminal 180, and comb electrodes 110b connected to ground. Second IDT-track 120 includes comb electrodes 120a connected to an output terminal 190, and comb electrodes 120b connected to ground. Third IDT-track 130 includes comb electrodes 130a connected to input terminal 180, and comb electrodes 130b connected to ground. Fourth IDT-track 140 includes comb electrodes 140a connected to output terminal 190, and comb electrodes 140b connected to ground. Fifth IDT-track 150 includes comb electrodes 150a connected to input terminal 180, and comb electrodes 150b connected to ground. The fingers 101 in comb electrodes 110a are pointing in the −Y direction and connected to output terminal 190, and the fingers 101 in comb electrodes 110b are pointing in the +Y direction opposite to the −Y direction and connected to input terminal 180 opposite to output terminal 190; the fingers 101 in comb electrodes 120a are pointing in the +Y direction and connected to input terminal 180, and the fingers 101 in comb electrodes 120b are pointing in the −Y direction and connected to output terminal 190; and so on. Thus, adjacent fingers 101 in IDT-tracks 110-150 have opposite polarities.

In some embodiments, within the set of N IDT-tracks 110-150, there exists a mirror symmetry relationship between an X-th IDT-track and an (N+1-X)-th IDT-track, relative to a center IDT-track. Here, X is an integer greater than or equal to 1, and less than or equal to N, and the center IDT-track is the (N+1)/2-th IDT-track. In other words, for a given track, labeled as the X-th IDT-track, there is a corresponding track on the opposite side of a center IDT-track, labeled as the (N+1)/2-th IDT-track. The corresponding track, labeled as the (N+1-X)-th IDT-track, is an mirror image of the X-th IDT-track. This symmetry is relative to the center IDT-track, which acts like a line of reflection. For example, in the embodiment illustrated in FIG. 1, first IDT-track 110 and fifth IDT-track 150 exhibit a mirror symmetry relationship relative to third IDT-track 130 (i.e., the center IDT-track); and second IDT-track 120 and fourth IDT-track 140 exhibit a mirror symmetry relationship relative to third IDT-track 130.

In some embodiments, a total number of fingers in each IDT-track is an odd number greater than or equal to 3. For example, in the embodiment illustrated in FIG. 1, first IDT-track 110 includes thirteen (13) fingers 101, six (6) belong to comb electrodes 110a and seven (7) belong to comb electrodes 110b. Second IDT-track 120 includes seven (7) fingers 101, three (3) belong to comb electrodes 120a and four (4) belong to comb electrodes 120b. Third IDT-track 130 includes eleven (11) fingers 101, five (5) belong to comb electrodes 130a and six (6) belong to comb electrodes 130b. Fourth IDT-track 140 includes seven (7) fingers 101, three (3) belong to comb electrodes 140a and four (4) belong to comb electrodes 140b. Fifth IDT-track 150 includes thirteen (13) fingers 101, six (6) belonging to comb electrodes 150a and seven (7) belong to comb electrodes 150b.

In some embodiments, within a group of IDT-tracks including a center IDT-track and the IDT-tracks positioned between the center IDT-track and one of reflectors 160 and 170, there is a variance in a total number of fingers in each respective IDT-track within the group. For example, in the embodiment illustrated in FIG. 1, within a particular group consisting of first IDT-track 110, second IDT-track 120, and third IDT-track 130 (i.e., the center IDT-track), the total number of fingers 101 across the individual IDT-tracks 110, 120, and 130 varies. That is, the total number of fingers 101 in first IDT-track 110 differs from the total number of fingers 101 in second IDT-track 120 (i.e., 13 and 7, respectively), which in turn differs from the total number of fingers 101 in third IDT-track 130 (i.e., 11). Similarly, within another group consisting of third IDT-track 130 (i.e., the center IDT-track), fourth IDT-track 140, and fifth IDT-track 150, the total number of fingers 101 across the individual IDT-tracks 130, 140, and 150 varies.

In some embodiments, each IDT-track includes at least a main resonance section (also referred to as “resonance section”) and a pitch modulation section (also referred to as “modulation section”). The main resonance section is responsible for creating a specific range of frequencies, known as a passband, that DMS filter 100 can effectively work with. The pitch modulation section mitigates a bulk acoustic wave radiation into piezoelectric substrate 10 of DMS filter 100, thus reducing insertion loss of DMS filter 100.

Within the group of N IDT-tracks positioned between the pair of reflectors 160 and 170, the first and N-th IDT-tracks each include a resonance section positioned adjacent to a reflector (160 or 170) and a modulation section positioned adjacent to an adjacent IDT-track. In contrast, the second through the (N−1)-th IDT-track each includes two modulation sections and a resonance section positioned between the two modulation sections. For example, in the embodiment illustrated in FIG. 1, first IDT-track 110 includes a resonance section 111 positioned adjacent to first reflector 160 and a modulation section 112 positioned adjacent to second IDT-track 120. Second IDT-track 120 includes a resonance section 121 positioned between two modulation sections 122. Similarly, third IDT-track 130 includes a resonance section 131 positioned between two modulation sections 132, while fourth IDT-track 140 includes a resonance section 141 positioned between two modulation sections 142. Lastly, fifth IDT-track 150 includes a modulation section 152 positioned adjacent to fourth IDT-track 140 and a resonance section 151 positioned adjacent to second reflector 170.

In some embodiments, within each IDT-track, a width of each finger 101 in the resonance section measured in the longitudinal direction is greater than a width of each finger 101 in the modulation section measured in the longitudinal direction. The width of each finger in the resonance section is, e.g., 1.05 to 1.15 times greater than the width of each finger in the modulation section. For example, in the embodiment illustrated in FIG. 1 (not drawn to scale), in first IDT-track 110, the width X1 of each finger 101 in resonance section 111 is greater than the width X2 of each finger 101 in modulation section 112. Also for example, in third IDT-track 130, the width X3 of each finger 101 in resonance section 131 is greater than the width X4 of each finger 101 in modulation section 132.

In some embodiments, within each IDT-track, a number of the fingers in the resonance section is greater than a number of the fingers in the modulation section. For example, in the embodiment illustrated in FIG. 1, in first IDT-track 110, resonant section 111 includes a greater number of fingers 101 (i.e., 9) than modulation section 112 that has 4 fingers 101. Likewise, in the second IDT-track 120, resonance section 121 includes a greater number of fingers 101 (i.e., 3) than modulation sections 122, each having only 2 fingers 101.

In some embodiments, within a group of IDT-tracks including the center IDT-track and the IDT-tracks positioned between the center IDT-track and one of the reflectors, a width of each finger in the resonance section of an IDT-track differs from a width of each finger in the resonance section of another IDT-track in the group. For example, in the embodiment illustrated in FIG. 1 (not drawn to scale), within a particular group consisting of first IDT-track 110, second IDT-track 120, and third IDT-track 130 (i.e., the center IDT-track), the width of each finger 101 in resonant section 111 of first IDT-track 110 differs from the width of each finger 101 in resonant section 121 of second IDT-track 120, which in turn differs from the width of each finger 101 in resonance section 131 of third IDT-track 130. Similarly, within another group consisting of third IDT-track 130 (i.e., the center IDT-track), fourth IDT-track 140, and fifth IDT-track 150, the width of each finger 101 in resonance section 131 of third IDT-track 130 differs from the width of each finger 101 in resonance section 141 of fourth IDT-track 140, which in turn differs from the width of each finger 101 in resonance section 151 of fifth IDT-track 150.

In some embodiments, within a group of IDT-tracks including the center IDT-track and the IDT-tracks positioned between the center IDT-track and one of the reflectors, a number of fingers in the resonance section of an IDT-track differs from a number of finger in the resonance section of another IDT-track in the group. For example, in the embodiment illustrated in FIG. 1, within a particular group consisting of first IDT-track 110, second IDT-track 120, and third IDT-track 130 (i.e., the center IDT-track), the number of fingers 101 in resonance section 111 of first IDT-track 110 differs from the number of fingers 101 in resonance section 121 of second IDT-track 120 (i.e., 9 and 3, respectively), which in turn differs from the number of fingers 101 in resonance section 131 of third IDT-track 130 (i.e., 5). Likewise, within another group consisting of third IDT-track 130 (i.e., the center IDT-track), fourth IDT-track 140, and fifth IDT-track 150, the number of fingers 101 in resonance section 131 of third IDT-track 130 differs from the number of fingers 101 in resonance section 141 of fourth IDT-track 140 (i.e., 5 and 3, respectively), which in turn differs from the number of fingers 101 in resonance section 151 of fifth IDT-track 150 (i.e., 9).

In some embodiments, each of reflectors 160 and 170 includes a plurality of reflector fingers 102. A width of each reflector finger 102 is greater than a width of each finger in the resonance section of an IDT-track. In the embodiment illustrated in FIG. 1 (not to scale), width X5 of each reflector finger 102 in first reflector 160 is greater than that of each finger 101 in resonance sections 111, 121, 131, 141, and 151 of the corresponding IDT-tracks 110, 120, 130, 140, and 150.

The DMS filter of the embodiments of the present disclosure effectively enhances out-of-band suppression by configuring the parameters of the IDT-track electrodes described above. Hence, the DMS filter of the embodiments of the present disclosure can work as a superior alternative for filter devices in duplexers and communication equipment.

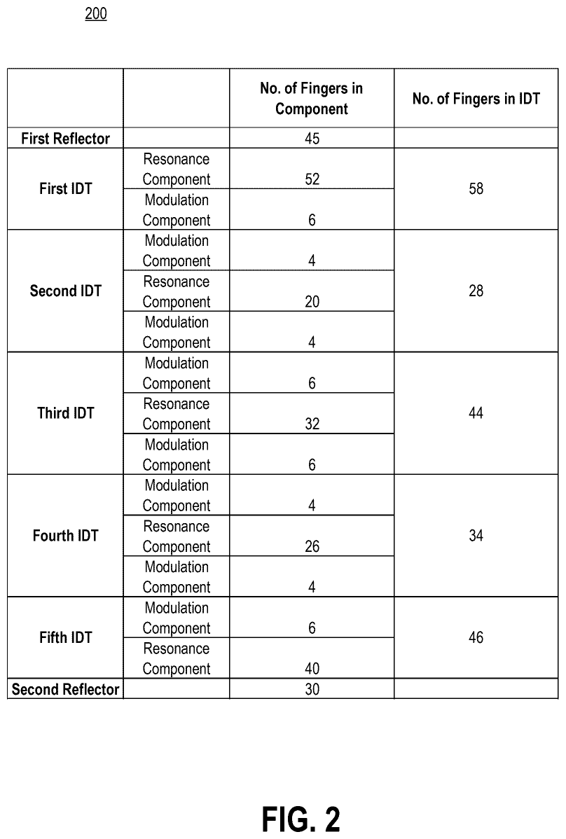

FIG. 2 is a table 200 summarizing parameters of a first DMS filter included in a first Band66 receive filter, according to an embodiment of the present disclosure. Similar to DMS filter 100 illustrated in FIG. 1, the first DMS filter summarized in table 200 includes a first reflector, a second reflector, and first through fifth IDT-tracks positioned between the first reflector and the second reflector. Table 200 lists the numbers of reflector fingers in the first reflector and the second reflector, as well as the numbers of the fingers in the modulation section and the resonance section of each of the first through fifth IDT-tracks. Table 200 also lists the total number of fingers in each of the first through fifth IDT-tracks. For example, as shown in FIG. 2, in the first IDT-track, the resonance component includes 52 fingers, and the modulation section includes 6 fingers, and thus the total number of fingers in the first IDT-track is 58. Similarly, in the second IDT-track, the resonance section includes 20 fingers, and each of the modulation sections includes 4 fingers, and thus the total number of fingers in the second IDT-track is 28. And so on. As can be seen from table 200, the total number of fingers in each one of the first through fifth IDT-tracks is an even number.

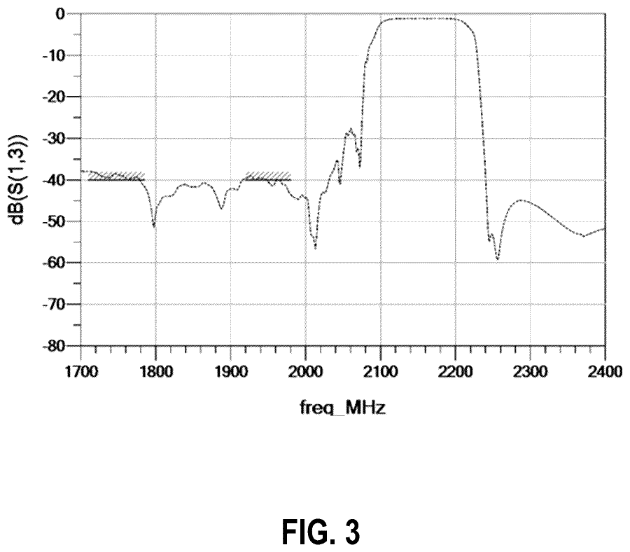

FIG. 3 is a graph of simulated frequency response for the first Band66 receive filter including the first DMS filter of FIG. 2. As can be seen, in Band3 (1710 MHz to 1785 MHZ) in the stop band at the low frequency side, the first Band66 receive filter has a suppression level of −37.8 dB. In Band1 (1920 MHz to 1980 MHZ) in the stop band at the low frequency side, the first Band66 receive filter has a suppression level of −40 dB.

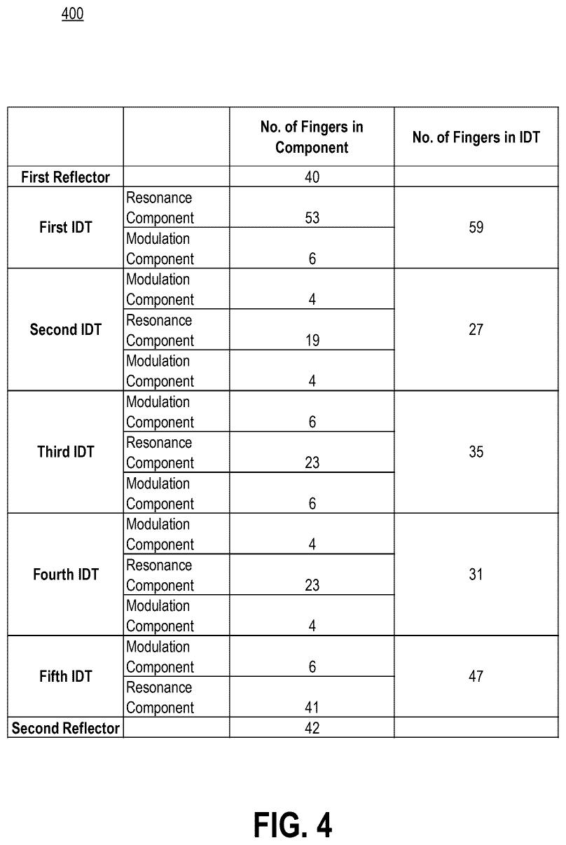

FIG. 4 is a table 400 summarizing parameters of a second DMS filter included in a second Band66 receive filter, according to an embodiment of the present invention. Similar to DMS filter 100 illustrated in FIG. 1, the second DMS filter summarized in table 400 includes a first reflector, a second reflector, and first through fifth IDT-tracks positioned between the first reflector and the second reflector. Table 400 also lists the total number of fingers in each of the first through fifth IDT-tracks. For example, as shown in FIG. 4, in the first IDT-track of the second DMS filter, the resonance section includes 53 fingers, and the modulation section includes 6 fingers, and thus the total number of fingers in the first IDT-track is 59. Similarly, in the second IDT-track of the second DMS filter, the resonance section includes 19 fingers, and each of the modulation sections includes 4 fingers, and thus the total number of fingers in the second IDT-track is 27. And so on. As can be seen from table 400, the total number of fingers in each one of the first through fifth IDT-tracks is an odd number.

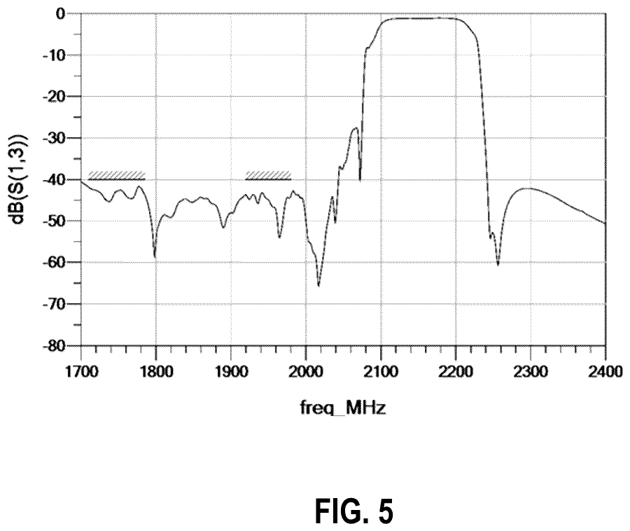

FIG. 5 is a graph of simulated frequency response for the second Band66 filter including the second DMS filter of the embodiment of the present disclosure. As can be seen, in Band3 (1710 MHz to 1785 MHZ) in the stop band at the low frequency side, the second Band66 receive filter has a suppression level of −42 dB. In Band1 (1920 MHz to 1980 MHZ) in the stop band at the low frequency side, the second Band66 receive filter has a suppression level of −45 dB. Thus, as for the stop-band suppression at the low frequency side, the second Band66 receive filter including the second DMS filter having the odd numbered fingers in each IDT-track excels the first Band66 receive filter including the first DMS filter having the even numbered fingers in each IDT-track.

Embodiments of the present disclosure also provide a hybrid-type receive filter using the DMS filter described above.

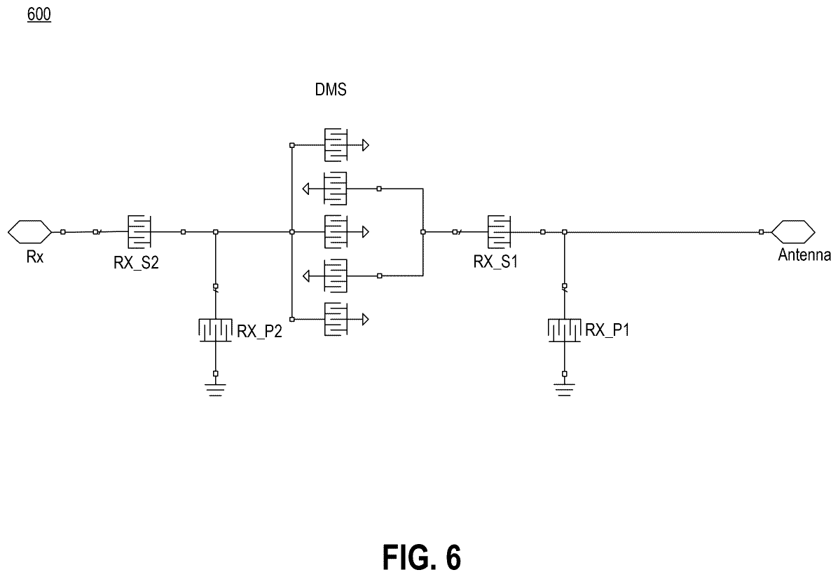

FIG. 6 illustrates a hybrid-type receive filter 600 according to an embodiment of the present disclosure. As illustrated in FIG. 6, hybrid-type filter 600 includes series resonators RX_S1 and RX_S2, parallel resonators RX_P1 and RX_P2, and a DMS filter, which may be the DMS filter described above. Resonator RX_S1, the DMS filter, and resonator RX_S2 are connected in series between a reception terminal Rx and an antenna terminal ANT. Resonator RX_P1 is connected between a port of resonator RX_S1 and ground. Resonator RX_P2 is connected between a port of resonator RX_S2 and ground. In hybrid-type receive filter 600, resonators RX_S1, RX_S2, RX_P1, and RX_P2 may be formed of one-port resonators.

Hybrid-type receive filter 600 is illustrated in FIG. 6 as an example, and the present disclosure is not limited thereto. For example, although two series resonators RX_S1 and RX_S2 and two parallel resonators RX_P1 and RX_P2 are illustrated in FIG. 6, other numbers of series resonators or parallel resonators may be used based on desired circuit parameters. The hybrid-type receive filter according to the embodiment of the present disclosure may have different circuit structures or include different circuit components, provided that it includes at least one DMS filter described above.

Embodiments of the present disclosure also provide a duplexer using the DMS filter described above.

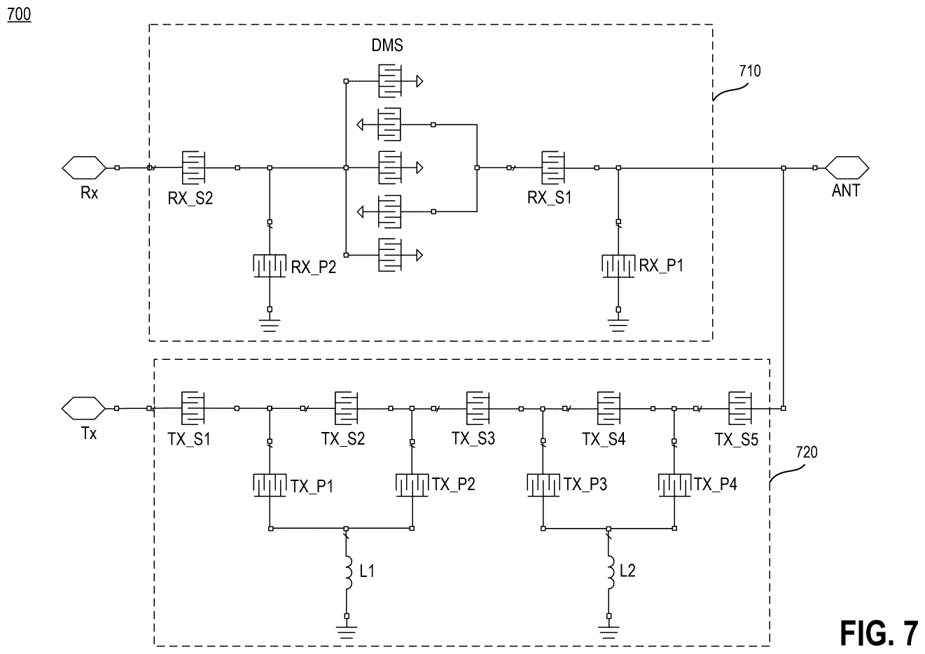

FIG. 7 illustrates a duplexer 700 according to an embodiment of the present disclosure. As illustrated in FIG. 7, duplexer 700 includes a receive filter 710 connected between a reception terminal Rx and an antenna terminal ANT, and a transmit filter 720 connected between a transmission terminal Tx and antenna terminal ANT.

Receive filter 710 includes series resonators RX_S1 and RX_S2, parallel resonators RX_P1 and RX_P2, and a DMS filter, which may be the DMS filter described above. Resonator RX_S1, the DMS filter, and resonator RX_S2 are connected in series between reception terminal Rx and antenna terminal ANT. Resonator RX_P1 is connected between a port of resonator RX_S1 and ground. Resonator RX_P2 is connected between a port of resonator RX_S2 and ground.

Transmit filter 720 includes series resonators TX_S1, TX_S2, TX_S3, TX_S4, and TX_S5, and parallel resonators TX_P1, TX_P2, TX_P3, and TX_P4. Resonators TX_S1, TX_S2, TX_S3, TX_S4, and TX_S5 are connected in series between transmission terminal Tx and antenna terminal ANT. Resonators TX_P1 and TX_P2 are connected between ports of resonators TX_S1 and TX_S2 and ground through an inductor L1, respectively. Resonators TX_P3 and TX_P4 are connected between ports of resonators TX_S3 and TX_S4 and ground through an inductor L2, respectively. Inductors L1 and L2 are generated by bonding wires between bare die and ground pattern of a package, or by inductors integrated in package.

In duplexer 700, the resonators, such as RX_S1, RX_S2, etc., may be formed of one-port resonators.

Duplexer 700 is illustrated in FIG. 7 as an example, and the present disclosure is not limited thereto. For example, although certain numbers of series resonators and parallel resonators are illustrated in FIG. 7, other numbers of series resonators or parallel resonators may be used based on desired circuit parameters. The duplexer according to the embodiment of the present disclosure may have different circuit structures or include different circuit components, provided it includes at least one DMS filter described above.

According to the embodiments of the present disclosure, the DMS filter can effectively improve the stop-band suppression level and suppress interference signals in adjacent frequency bands. This is achieved by reasonably configuring the parameters of the IDT-track interdigital electrodes. As a result, the DMS filter according to the embodiments of the present disclosure can be used in a duplexer or a filter for communication equipment. It is a superior choice for communication equipment due to its ability to suppress interference signals and improve the overall performance of the equipment.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable subcombination or as suitable in any other described embodiment of the present disclosure. Certain features described in the context of various embodiments may not be essential features of those embodiments, unless noted as such.

It is appreciated that, although terms such as “first” and “second” are used herein for describing various elements, the elements should not be limited by these terms, which are only used for distinguishing the elements. For example, a first element may also be referred to as a second element, and similarly, the second element may also be referred to as the first element, without departing from the spirit and scope of the present disclosure.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

Moreover, while illustrative embodiments have been described herein, the scope of any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application. The examples are to be construed as non-exclusive. Furthermore, the steps of the disclosed methods may be modified in any manner, including by reordering steps and/or inserting or deleting steps. It is intended, therefore, that the specification and examples be considered as illustrative only, with a true scope and spirit being indicated by the following claims and their full scope of equivalents.

What is claimed is:

1. A double-mode surface acoustic wave (DMS) filter, comprising:
a piezoelectric substrate;
a pair of reflectors disposed on the piezoelectric substrate; and
N interdigital transducer tracks (IDT-tracks) disposed on the piezoelectric substrate and between the pair of reflectors, and alternately arranged along a longitudinal direction, each IDT-track including a pair of comb electrodes with a plurality of fingers, and adjacent fingers having opposite polarities,
wherein a total number of fingers in each IDT-track is an odd number greater than or equal to 3, and N is an integer greater than or equal to 3.

2. The DMS filter of claim 1, wherein N is an odd number greater than or equal to 5.

3. The DMS filter of claim 2, wherein among the N IDT-tracks, an X-th IDT-track and an (N+1-X)-th IDT-track have a mirror symmetry relationship with respect to a center IDT-track, where X is an integer greater than or equal to 1, and less than or equal to N, and the center IDT-track is a (N+1)/2-th IDT-track.

4. The DMS filter of claim 1, wherein within a group of IDT-tracks including a center IDT-track and IDT-tracks arranged between the center IDT-track and one of the reflectors, a total number of fingers in an IDT-track is different from a total number of fingers in another IDT-track in the group.

5. The DMS filter of claim 1, wherein each IDT-track includes at least a resonance section and a modulation section.

6. The DMS filter of claim 5, wherein, within each IDT-track, a width of each finger in the resonance section measured in the longitudinal direction is greater than a width of each finger in the modulation section measured in the longitudinal direction.

7. The DMS filter of claim 6, wherein, within each IDT-track, the width of each finger in the resonance section is 1.05 to 1.15 times the width of each finger in the modulation section.

8. The DMS filter of claim 5, wherein, within each IDT-track, a number of the fingers in the resonance section is greater than a number of the fingers in the modulation section.

9. The DMS filter of claim 5, wherein within a group of IDT-tracks including a center IDT-track and IDT-tracks between the center IDT-track and one of the reflectors, a width of each finger in the resonance section of an IDT-track is different from a width of each finger in the resonance section of another IDT-track in the group.

10. The DMS filter of claim 5, wherein within a group of IDT-tracks including a center IDT-track and IDT-tracks between the center IDT-track and one of the reflectors, a number of fingers in the resonance section of an IDT-track is different from a number of finger in the resonance section of another IDT-track in the group.

11. The DMS filter of claim 5, wherein each one of the reflectors includes a plurality of reflector fingers, and a width of each reflector finger is greater than a width of each finger in the resonance section of at least one of the IDT-tracks disposed between the reflectors.

12. The DMS filter of claim 5, wherein each one of the first and the N-th IDT-track includes a resonance section arranged adjacent to one of the reflectors, and a modulation section arranged adjacent to an adjacent IDT-track.

13. The DMS filter of claim 5, wherein each one of the second to the (N−1)-th IDT-track includes two modulation sections and a resonance section between the two modulation sections.

14. A receive filter, comprising:
a double-mode surface acoustic wave (DMS) filter, comprising:
a piezoelectric substrate;
a pair of reflectors disposed on the piezoelectric substrate; and
N interdigital transducer tracks (IDT-tracks) disposed on the piezoelectric substrate and between the pair of reflectors, and alternately arranged along a longitudinal direction, each IDT-track including a pair of comb electrodes with a plurality of fingers, and adjacent fingers having opposite polarities, wherein a total number of fingers in each IDT-track is an odd number greater than or equal to 3.

15. A duplexer, comprising:
a transmit filter; and
a receive filter,
wherein the receive filter includes a double-mode surface acoustic wave (DMS) filter, comprising:
a piezoelectric substrate;
a pair of reflectors disposed on the piezoelectric substrate; and
N interdigital transducer tracks (IDT-tracks) disposed on the piezoelectric substrate and between the pair of reflectors, and alternately arranged along a longitudinal direction, each IDT-track including a pair of comb electrodes with a plurality of fingers, and adjacent fingers having opposite polarities,
wherein a total number of fingers in each IDT-track is an odd number greater than or equal to 3.
